(19) United States
(12) Patent Application Publication
(10) Pub. No.: US 2005/0077572 A1
(43) Pub. Date: Apr. 14, 2005

(54) Semiconductor device having periodic construction

(76) Inventors: Shoichi Yamauchi, Nagoya-city (JP); Mikimasa Suzuki, Toyohashi-city (JP); Yoshiyuki Hattori, Aichi-gun (JP); Kyoko Nakashima, Nagoya-city (JP)

Correspondence Address: POSZ & BETHARDS, PLC, 11250 ROGER BACON DRIVE, SUITE 10, RESTON, VA, 20190, US

(21) Appl. No.: 10/960,286

(22) Filed: Oct. 8, 2004

(30) Foreign Application Priority Data
Oct. 10, 2003 (JP) 2003-352335

(51) Int. Cl. H01L 29/49

(52) U.S. Cl. 257/341

(57) ABSTRACT

A device includes a center portion, and a periphery portion disposed around the center portion. The periphery portion includes a first semiconductor layer, an intermediate layer, a second semiconductor layer, an insulation layer and an electrode. The intermediate layer includes a periodic construction having a first region and a second region. The center portion includes a contact region. The electrode extends to the periphery portion to have an extension length of the electrode between the contact region and a periphery of the electrode. The extension length of the electrode is equal to or longer than one-eighth of a distance between the contact region and an outer periphery of the periodic construction.

### CROSS REFERENCE TO RELATED APPLICATION

This application is based on Japanese Patent Application No. 2003-352335 filed on Oct. 10, 2003, the disclosure of which is incorporated herein by reference.

### FIELD OF THE INVENTION

The present invention relates to a semiconductor device having a periodic construction.

### BACKGROUND OF THE INVENTION

A semiconductor device having a periodic construction, i.e., a super junction construction is disclosed in Unexamined Japanese Patent Application Publication No. 2002-184985 (which corresponds to U.S. Pat. No. 6,639,260-B2 and U.S. patent application Publication No. 2002-0074596-A1). The super junction construction is such that the device includes the first region having the first conductive type and the second region having the second conductive type, which are laminated each other in a horizontal direction (i.e., a repeating direction). Specifically, the first conductive type is a N type conductivity, and the second conductive type is a p type conductivity. Thus, the first region is a N type column, and the second region is a P type column. The N type column includes a N type impurity, and the P type column includes a P type impurity. The N type column and the P type column provide a unit so that multiple units, i.e., the N type columns and the P type columns, are laminated alternately in a drift region of the device. In the device having the super junction construction, withstand voltage of the device is increased, and further, the resistance of the drift region is reduced. Thus, the device has a high withstand voltage and a low On-state resistance.

The device includes a center portion having a switching device and a periphery portion having no switching device. The periphery portion of the device is disposed around the center portion of the device. In the device, it is required to increase an Off-state withstand voltage. Therefore, it is required to increase the Off-state withstand voltage of both of the center portion and the periphery portion. The super junction construction of the device is formed continuously in both of the center portion and the periphery portion. Thus, since the super junction construction is formed in the periphery portion, a depletion layer is expanded in the periphery portion. Therefore, the Off-state withstand voltage of the periphery portion can be increased. Here, the Off-state withstand voltage of the center portion of the device is also increased.

In the device disclosed in JP 2002-184985, by using a P type contact region formed in the center portion of the device, the P type column of the periphery portion is connected to a source electrode. Thus, the depletion layer is easily expanded in the periphery portion, so that the withstand voltage of the periphery portion is increased.

However, it is required to increase the withstand voltage of the periphery portion much higher.

### SUMMARY OF THE INVENTION

In view of the above-described problem, it is an object of the present invention to provide a semiconductor device with a periodic construction having high withstand voltage.

A device includes a center portion and a periphery portion disposed around the center portion. The periphery portion includes a first semiconductor layer, an intermediate layer, a second semiconductor layer, an insulation layer and an electrode, which are laminated in this order. The intermediate layer includes a periodic construction having a first region and a second region, which are repeated alternately in a repeating direction parallel to the first and second semiconductor layers. The center portion includes a contact region. The electrode extends to the periphery portion to have an extension length of the electrode, which is defined as a length of the electrode between the contact region and a periphery of the electrode disposed in the periphery portion. The extension length of the electrode is equal to or longer than one-eighth of a distance between the contact region and an outer periphery of the periodic construction.

In the above device, the electric field distribution in the second semiconductor layer between the contact region and the periphery of the periodic construction is uniformed, so that the Off-state withstand voltage of the periphery portion is increased. Thus, the semiconductor device with the periodic construction has high withstand voltage.

Preferably, the center portion includes a semiconductor switching device. The periphery portion includes no semiconductor switching device. The first semiconductor layer has a first conductive type, and the second semiconductor layer has a second conductive type. The intermediate layer divides the first and second semiconductor layers. The first region of the periodic construction has the first conductive type, and the second region of the periodic construction has the second conductive type. The center portion includes multiple contact regions having the second conductive type so that an utmost outer contact region is disposed on utmost outside of the center portion. The electrode contacts the contact regions, and electrically connected to the second semiconductor layer in the periphery portion through the utmost outer contact region. The extension length of the electrode is defined a length between the utmost outer contact region and the periphery of the electrode disposed in the periphery portion.

More preferably, the first semiconductor layer is disposed on a backside of the device, and the second semiconductor layer is disposed on a foreside of the device. The insulation layer is disposed on a part of the second semiconductor layer. The electrode is disposed on a part of the insulation layer and on another part of the second semiconductor layer. The first region extends between the first semiconductor layer and the second semiconductor layer, and the second region extends between the second semiconductor layer and the first semiconductor layer.

Further, a device includes: a center portion having a semiconductor switching device; and a periphery portion disposed around the center portion and having no semiconductor switching device. The periphery portion includes a first semiconductor layer having a first conductive type and disposed on a backside of the device, an intermediate layer, a second semiconductor layer having a second conductive type and disposed on a foreside of the device, an insulation layer, and an electrode, which are disposed in this order. The intermediate layer divides the first and second semiconductor layers. The insulation layer is disposed on a part of the second semiconductor layer. The electrode is disposed on a part of the insulation layer and on another part of the second semiconductor layer. The intermediate layer includes a periodic construction having a first region with the first conductive type and a second region with the second conductive type, which are repeated alternately in a repeating direction parallel to the first and second semiconductor layers. The first region extends from the first semiconductor layer to the second semiconductor layer, and the second region extends from the second semiconductor layer to the first semiconductor layer. The center portion includes multiple contact regions having the second conductive type so that an utmost outer contact region is disposed on utmost outside of the center portion. The electrode contacts the contact regions, and electrically connected to the second semiconductor layer in the periphery portion through the utmost outer contact region. The electrode exceeds the first or second region adjacent to the utmost outer contact region and extends to the periphery portion.

In the above device, the electric field distribution in the second semiconductor layer between the contact region and the periphery of the periodic construction is uniformed, so that the Off-state withstand voltage of the periphery portion is increased. Thus, the semiconductor device with the periodic construction has high withstand voltage.

Furthermore, a device includes: a first semiconductor layer having a first conductive type and disposed on a backside of the device; a second semiconductor layer having a second conductive type and disposed on a foreside of the device; an intermediate layer for dividing the first and second semiconductor layers; a contact region having the second conductive type and disposed on a part of the second semiconductor layer; an insulation layer for covering a surface of the second semiconductor layer; and an electrode disposed on the insulation layer. The intermediate layer includes a periodic construction having a first region with the first conductive type and a second region with the second conductive type, which are repeated alternately in a repeating direction parallel to the first and second semiconductor layers. The first region extends between the first semiconductor layer and the second semiconductor layer, and the second region extends between the second semiconductor layer and the first semiconductor layer. The electrode is electrically connected to the second semiconductor layer through the contact region. The electrode exceeds the first or second region in the periodic construction adjacent to the contact region and extends on the insulation layer.

In the above device, the electric field distribution in the second semiconductor layer between the contact region and the periphery of the periodic construction is uniformed, so that the Off-state withstand voltage of the periphery portion is increased. Thus, the semiconductor device with the periodic construction has high withstand voltage.

### BRIEF DESCRIPTION OF THE DRAWINGS

The above and other objects, features and advantages of the present invention will become more apparent from the following detailed description made with reference to the accompanying drawings. In the drawings:

FIG. 1 is a perspective view showing a semiconductor device according to a first embodiment of the present invention;

FIG. 2 is a partial plan view showing the device according to the first embodiment;

FIG. 3 is a cross sectional view showing a semiconductor device according to a second embodiment of the present invention;

FIG. 4 is a cross sectional view showing a semiconductor device as a comparison of the device according to the second embodiment;

FIG. 5 is a cross sectional view explaining an impact ion easily generation portion of the semiconductor device according to the second embodiment;

FIG. 6 is a graph showing a relationship between a withstand voltage of the device and a ratio of Y/X, according to the second embodiment;

FIG. 7 is a cross sectional view showing a semiconductor device as another comparison of the device according to the second embodiment;

FIG. 8 is a graph showing a relationship between electric field intensity and a position on line VIIIA-VIIIA in FIG. 3, VIIIB-VIIIB in FIG. 4, or VIIIC-VIIIC in FIG. 7, according to the second embodiment; and

FIG. 9 is a graph showing a relationship between a withstand voltage and a ratio of Y/X in two different devices according to a third embodiment of the present invention.

### DETAILED DESCRIPTION OF THE PREFERRED EMBODIMENTS

### First Embodiment

The inventors have preliminarily studied about a semiconductor device having a super junction construction. Specifically, the device includes a periphery portion and a center portion. Both of the center portion and the periphery portion have the super junction construction. The super junction construction includes a P type column and an N type column, which provide a periodic construction and are alternately disposed and repeated in a repeating direction. By using a P type contact region disposed in the center portion, the P type column disposed in the periphery portion is connected to a source electrode. A brake down phenomenon occurred in the periphery portion is studied by the inventors. As a result, electric field is concentrated at around an interface between a contact region disposed on utmost outer periphery of the center portion and a part of the periphery portion, which has the same conductive type as the contact region. Thus, the brake down phenomenon is occurred around the interface between the utmost outer contact region and the part of the periphery portion. Here, the contact region includes a high concentration impurity, and the periphery portion includes a low concentration impurity. Therefore, even when the conductive type of the contact region is equal to the conductive type of the part of the periphery portion, the electric field is concentrated at the interface therebetween. Thus, the brake down phenomenon is occurred at the interface.

To obtain a semiconductor device having high withstand voltage, it is required to reduce the electric field concentration around the interface between the utmost outer contact region and the part of the periphery portion having the same conductive type as the utmost outer contact region. Specifically, in the device according to this embodiment, an electrode connecting to the contact region in the center portion of the device is extended to the periphery portion so that the Off-state withstand voltage of the periphery portion is increased.

In the device, the switching device is formed in the center portion. The periphery portion is disposed around the center portion. The periphery portion includes the first semiconductor layer having the first conductive type, the second semiconductor layer having the second conductive type, an intermediate layer, an insulation layer, and an electrode. The first semiconductor layer is disposed on a backside of the device, and the second semiconductor layer is disposed on a foreside of the device. The intermediate layer separates the first and second semiconductor layers. The insulation layer covers the surface of the second semiconductor layer. The electrode is formed on the surface of the insulation layer. The intermediate layer has the super junction construction. Specifically, the intermediate layer includes the first regions having the first conductive type and the second regions having the second conductive type, which are laminated alternately in the repeating direction. Each first region extends from the first semiconductor layer to the second semiconductor layer. Each second region extends from the second semiconductor layer to the first semiconductor layer. A laminating direction (i.e., the repeating direction) of the intermediate layer is parallel to the first and second semiconductor layers. This is, the laminating direction is perpendicular to a vertical direction for connecting between the first semiconductor layer and the second semiconductor layer. Thus, the first and second regions are repeated in a horizontal direction.

The electrode disposed on the surface of the insulation layer of the periphery portion contacts a contact region having the second conductive type, which is disposed in the center portion of the device. The electrode is connected to the second semiconductor layer in the periphery portion through the contact region disposed on an utmost outer periphery of the center portion. The electrode extends to the periphery portion so that the length of the electrode in the periphery portion is equal to or larger than one-eighth of the distance between the contact region disposed on the utmost outer periphery of the center portion and an outer periphery of the super junction construction formed in the intermediate layer.

The first and second regions have a certain shape such as a thin plate shape, a quadratic prism shape, or a hexagonal cylinder shape. The super junction construction can be provided such that the first region expands widely in the intermediate layer between the first and second semiconductor layers, and multiple second regions having a columnar shape are dispersed and disposed in the first region. In this case, multiple units composed of the first and second regions are repeated in a certain direction, and the units are disposed between the first and second semiconductor layers.

The electrode is, for example, a source electrode for connecting between a source region and a body contact region, which are disposed in the center portion. Here, the brake down phenomenon is easily occurred near the interface between the contact region disposed on the utmost outer periphery of the center portion and the part of the periphery portion having the same conductive type as the utmost outer contact region. Specifically, the interface is disposed between the body contact region having high concentration impurity and a semiconductor layer of the periphery portion having low concentration impurity. The semiconductor layer of the periphery portion surrounds the body contact region. The electric field is easily concentrated at a part of the interface of the body contact region having large curvature. The brake down phenomenon is occurred at the part of the interface. Therefore, to increase the Off-state withstand voltage of the periphery portion, it is required to reduce the electric field concentration near the body contact region disposed on the utmost outer periphery of the center portion.

In a prior art, a guard ring construction is provided to increase the withstand voltage of the periphery portion. In the guard ring construction, a guard ring having different conductive type different from a semiconductor substrate of the device is formed in the periphery portion. The electric field is easily concentrated at an interface of the guard ring. To reduce the electric filed concentration near a P-N junction of the interface of the guard ring, an electrode is formed on the surface of the guard ring through an insulation film. In this case, the electrode facing the guard ring through the insulation film works for reducing the electric filed concentration. However, in this case, the guard ring has the different conductive type different from the semiconductor substrate. In a device having a super junction construction in the prior art, an electrode for connecting to a contact region does not extend to the periphery portion. Even if the electrode reaches the periphery portion in case of a manufacturing error, the electrode does not extend to the periphery portion sufficiently. Specifically, an extension of the electrode to the periphery portion provides merely to cover the whole area of the contact region with the electrode. Therefore, the extension of the electrode is small, and, for example, is in a range between 0.5 μm and 1.0 μm. Specifically, the electrode does not exceed the part of the periphery portion adjacent to the utmost outer contact region, and does not extend to the periphery portion sufficiently. Therefore, the extension of the electrode does not affect to increase the Off-state withstand voltage.

However, in the device according to the first embodiment, by using the electrode facing the contact region through the insulation film, the electric field concentration is reduced so that the withstand voltage is increased. This is because the electric field is concentrated at the interface between the contact region and the semiconductor layer of the periphery portion, which has the same conductive type as the contact region. Specifically, the electrode extends to the periphery portion so that the length of the electrode in the periphery portion is equal to or larger than one-eighth of the distance between the contact region disposed on the utmost outer periphery of the center portion and the outer periphery of the super junction construction formed in the intermediate layer. In this case, the withstand voltage of the periphery portion is much improved. Here, the switching device disposed in the center portion does not affect the reduction of the electric field concentration of the periphery portion.

Preferably, the length of the electrode in the periphery portion is in a range between one-eighth and seven-eighths of the distance between the utmost outer contact region and the outer periphery of the super junction construction. In this case, since the electrode extends to almost the periphery of the super junction construction, the electric field concentration may be occurred in the second semiconductor layer disposed upside of the periphery of the super junction construction. However, when the length of the electrode is in a range between one-eighth and seven-eighths of the distance, electric field intensity distribution in the second semiconductor layer is uniformed so that the electric field concentration is reduced. The second semiconductor layer is disposed between the contact region on the utmost outer periphery of the center portion and the periphery of the super junction construction. This effect of the improvement of the Off-state withstand voltage of the device has been experimentally studied.

The device can include the electrode connecting to the second semiconductor layer of the periphery portion through the contact region disposed on the utmost outer periphery of the center portion and contacting the contact region having the second conductive type and disposed in the center region of the device. The electrode extends to the periphery portion and exceeds a part of the periphery portion, which is adjacent to a part of the contact region disposed on the utmost outer periphery of the center portion. The part of the contact region is disposed downside of the contact region. In this case, when the part of the periphery portion adjacent to the lower part of the utmost outer contact region is the first region, the electrode preferably extends to the periphery portion in such a manner that the electrode exceeds the second region adjacent to the first portion. To reduce the electric field concentration near the contact region disposed on the utmost outer periphery of the center portion, it is necessitated that the electrode exceeds the utmost outer contact region and extends to the periphery portion. When the electrode exceeds the part of the periphery portion adjacent to the utmost outer contact region, the electric field concentration concentrated at the interface between the contact region and the second semiconductor layer is reduced.

Preferably, the electrode extends to the periphery portion in such a manner that the electrode exceeds the part of the periphery portion adjacent to the utmost outer contact region of the center portion and the electrode does not reach the utmost outer periphery of the super junction construction disposed in the intermediate layer. Here, the part of the periphery portion is disposed under the utmost outer contact region. In this case, the electric field concentration near the interface between the contact region and the second semiconductor layer is reduced, and further, the electric field is prevented from concentrating in the second semiconductor layer disposed around the periphery of the super junction construction. Accordingly, the electric field distribution in the second semiconductor disposed between the contact region on the utmost outer periphery of the center portion and the periphery of the super junction construction is uniformed, so that the Off-state withstand voltage of the periphery portion is increased.

Preferably, the super junction construction composing the unit of the first and second regions laminated alternately in the intermediate layer of the periphery portion extends the center portion. Specifically, the device includes the drift region of the semiconductor switching device in the center portion having the super junction construction. In this case, the super junction construction of the center portion and the super junction construction of the periphery portion can be formed in the same process. Thus, the manufacturing cost is reduced. Further, the withstand voltage of the device becomes higher, and the On-state resistance becomes lower.

The above construction for reducing the electric field concentration can be used for another device, which includes the first semiconductor layer having the first conductive type and disposed on the backside of the device, the second semiconductor layer having the second conductive type and disposed on the foreside of the device, the intermediate layer for separating the first and second semiconductor layers, the contact region disposed in the second semiconductor layer with a predetermined arrangement, the insulation layer for covering the second semiconductor layer, and the electrode disposed on the surface of the insulation layer. In the intermediate layer, multiple units composed of the first and second regions are repeated in a certain direction, and the units are disposed between the first and second semiconductor layers. The first region having the first conductive type extends from the first semiconductor layer to the second semiconductor layer, and the second region having the second conductive type extends from the second semiconductor layer to the first semiconductor layer. The electrode connects to the second semiconductor layer through the contact region. The electrode exceeds the part of the periphery portion adjacent to the utmost outer contact region, and disposed on the surface of the insulation layer. In this case, by using the electrode, the electric field concentration near the interface between the utmost outer contact region having the second conductive type and disposed in the second semiconductor layer and the second semiconductor layer disposed on the super junction construction is reduced. The depletion layer is extended from the interface between the second semiconductor layer and the super junction construction, and the depletion layer is extended in the second semiconductor layer on the super junction construction. The width of the depletion layer in a horizontal direction is almost the same as the width of the super junction construction. The electric field intensity distribution in the second semiconductor layer is uniformed, since the electrode extends on the insulation layer and exceeds the part of the periphery portion adjacent to the utmost outer contact region. Thus, the withstand voltage of the device is increased.

The Off-state withstand voltage of the periphery portion is increased so that the Off-state withstand voltage of the device is improved. Here, the electrode is appropriately arranged so that the dimensions of the device are compactly designed.

Next, the device according to the first embodiment of the present invention is described in detail as follows.

The device includes the super junction construction disposed on the first conductive type semiconductor layer and the second conductive type semiconductor layer disposed on the super junction construction. In the center portion of the device, the first conductive type semiconductor layer provides a drain region, the super junction construction provides a drift region, and the second conductive type semiconductor layer provides a body region. On the surface of the body region of the second conductive type semiconductor layer, the first conductive type semiconductor region as a source region is formed. On the surface of the second conductive type semiconductor layer, the second conductive type semiconductor region as a body contact region is formed. A trench is formed in the body region having the second conductive type for separating the first conductive type semiconductor cell and the first conductive type source region. A trench gate electrode is formed in the trench. The trench gate electrode faces the body region through the insulation layer. The source region and the body contact region contact a common electrode. Thus, a trench gate type MOS transistor is formed in the center portion. The first conductive type semiconductor layer, the super junction construction disposed on the first conductive type semiconductor layer, the second conductive type semiconductor layer disposed on the super junction construction extend to the periphery portion. The source region, body contact region, and the trench gate electrode are not formed in the periphery portion. The second conductive type semiconductor layer is connected to the common electrode through the body contact region.

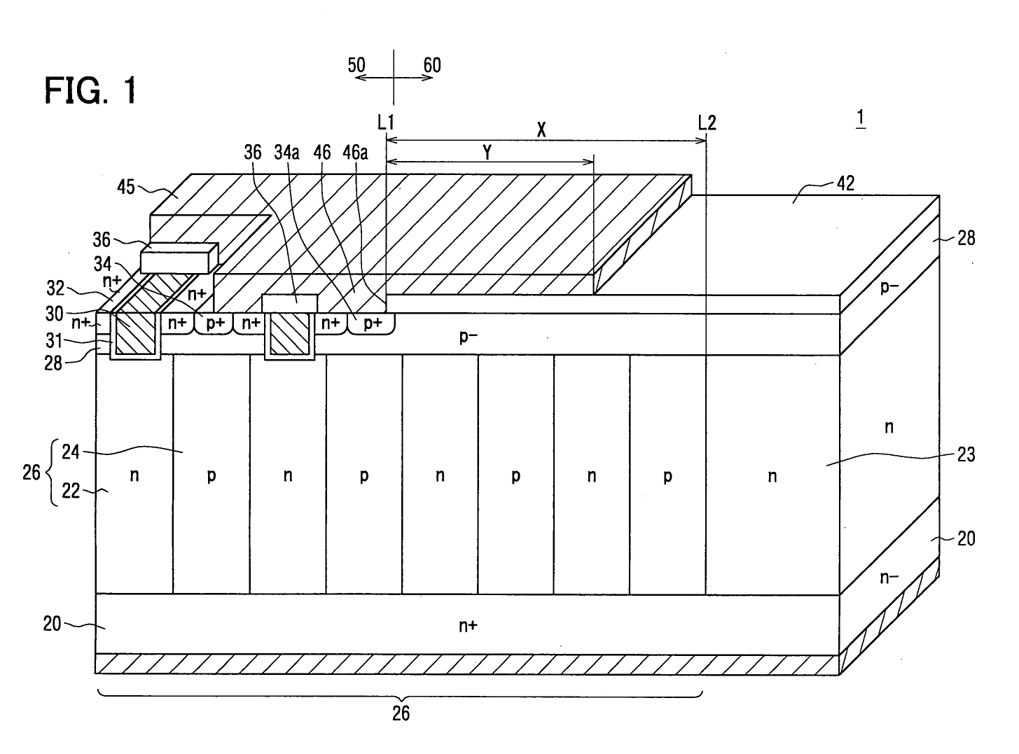

In FIG. 1, the device 1 according to the first embodiment is shown. The device 1 includes the center portion 50 and the periphery portion 60. Multiple semiconductor switching devices are formed in the center portion 50. The periphery portion 60 is disposed around the center portion 50. The center portion 50 and the periphery portion 60 are formed on the same semiconductor substrate. A periodic construction 26 as the super junction construction of the device 1 is disposed from the center portion 50 to the periphery portion 60.

In the center portion 50, the trench gate electrode 30 and the source region 32 are formed so that they work as the switching device. In FIG. 1, the switching device is a vertical type field effect transistor having the trench gate electrode 30.

A common part of the center portion 50 and the periphery portion 60 is described as follows. The first semiconductor layer 20 having the N⁺ conductive type as the first conductive type is formed on the backside of the device 1. The first semiconductor layer 20 is made of silicon single crystal. The second semiconductor layer 28 having the P⁻ conductive type as the second conductive type is formed on the foreside of the device 1. The second semiconductor layer 28 is made of silicon single crystal. The periodic construction 26 as the intermediate layer is formed between the first and second semiconductor layers 20, 28 for separating the layers 20, 28. An end region 23 is disposed on utmost outside of the periphery of the intermediate layer 26. The end region 23 is disposed in the periphery portion 60. The periodic construction 26 includes a unit having the first and second regions 22, 24. The first region 22 extends from the first semiconductor layer 20 to the second semiconductor layer 28. The first region 22 has the N conductive type. The second region 24 extends from the second semiconductor layer 28 to the first semiconductor layer 20. The second region 24 has the P conductive type. Multiple units are repeatedly disposed between the first and second semiconductor layers 20, 28. A repeating direction of the first and second regions 22, 24 is parallel to the first and second semiconductor layers 20, 28. Specifically, the repeating direction is perpendicular to a vertical direction for connecting between the first semiconductor layer 20 and the second semiconductor layer 28. The first and second regions 22, 24 have a thin plate shape, respectively. Specifically, the first and second regions 22, 24 have a striped construction in view of a plan view perpendicular to the repeating direction.

In the periphery portion 60, the source region 32, the trench gate electrode 30 and the body contact region 34 are not formed. The periphery portion 60 includes the insulation layer 42 and the source electrode 45. The insulation layer 42 covers the surface of the second semiconductor layer 28. The source electrode 45 is disposed on the surface of the insulation layer 42. The source electrode 45 is made of, for example, aluminum. Preferably, the insulation layer 42 has the sufficient thickness so that the upper portion of the second semiconductor layer 28 is not reversed by the source electrode 45. For example, the thickness of the insulation layer 42 is about 1 μm to 10 μm. More preferably, the thickness of the insulation layer 42 is in a range between 1.2 μm and 1.5 μm. In this case, when the device is in the Off-state, the depletion layer is formed in a wide region in the second semiconductor layer 28. The source electrode 45 disposed on the surface of the insulation layer 42 effectively works for reducing the electric filed concentration. The number of the units composed of the first and second regions 22, 24 in the periodic construction 26 is set to be an appropriate number.

In the center portion 50, the source region 32 and the contact region 34 are disposed. The source region 32 includes the N⁺ conductive type impurity, and the contact region 34 includes the P⁺ conductive type impurity. The source region 32 and the contact region 34 are disposed in the second semiconductor layer 28. The source region 32 and the contact region 34 contact the source electrode 45. Accordingly, the second semiconductor layer 28 connects to the source electrode 45 through the contact region 34 so that the second semiconductor layer 28 has the same electric potential as the source electrode 45. The source region 32 and the contact region 34 connect to the source electrode 45 through a contact hole 46.

The trench gate electrode 30 faces the second semiconductor layer 28 through a gate insulation film 31. The second semiconductor layer 28 is disposed between the first region 22 of the periodic construction 26 and the source region 32. The trench gate electrode 30 is made of, for example, poly silicon. The trench gate electrode 30 is parallel to the stripe of the periodic construction 26. This is, the trench gate electrode 30 is perpendicular to the repeating direction of the periodic construction 26. The insulation layer 36 covers the surface of the trench gate electrode 30 so that the trench gate electrode 30 is insulated from the source electrode 45 disposed on the trench gate electrode 30. When a positive voltage is applied to the trench gate electrode 30, the second semiconductor layer 28 facing the trench gate electrode 30 is reversed from the P⁻ conductive type to the N conductive type so that the source region 32 is electrically connected to the first semiconductor layer 20 through the first region 22 and the reversed second semiconductor layer 28.

In the prior art, the source electrode 45 is formed in an upper portion of the center portion 50. This is, the source electrode 45 is disposed inside of the utmost outer contact region 34a of the center region 50. Specifically, the source electrode 45 is disposed inside of a line L1 shown in FIG. 1. Therefore, no source electrode 45 is disposed outside of the line L1. Here, the utmost outer contact region 34a of the center portion 50 is disposed at the utmost outside of the center portion 50. Thus, the line L1 coincides with a sidewall 46a of the contact hole 46, which is disposed outside of the device 1 and works for connecting between the utmost outer contact region 34a and the source electrode 45. This is, the line L1 coincides with a sidewall of the insulation layer 42, which is the sidewall 46a of the contact hole 46 and disposed on a center portion side.

In the device 1, a distance X is defined between the utmost outer contact region 34a and the end line L2 of the periodic construction 26, which is disposed outside of the periodic construction 26. Specifically, the distance X is defined between the line L1 and the end L2. An extension length Y is defined between the line L1 and an end of the source electrode 45, which is disposed outside of the device 1 in the periphery portion 60. Thus, the source electrode 45 extends to the periphery portion side by the extension length Y. Here, the length Y is equal to or shorter than the distance X. Therefore, the source electrode 45 has a length in the repeating direction of the periodic construction 26, which is longer by the length Y than that of the device in the prior art. Specifically, the device in the prior art has the source electrode disposed only on the center portion. However, the device 1 in this embodiment has the source electrode 45 disposed on both of the center portion 50 and the periphery portion 60. Thus, the source electrode 45 extend to the periphery portion 60 so that the Off-state withstand voltage of the periphery portion is increased. The source electrode 45 extends to the periphery portion 60 in a range of the distance X. Preferably, the extension length Y of the source electrode 45 is in a range between one-eighths of the distance X and seven-eighths of the distance X.

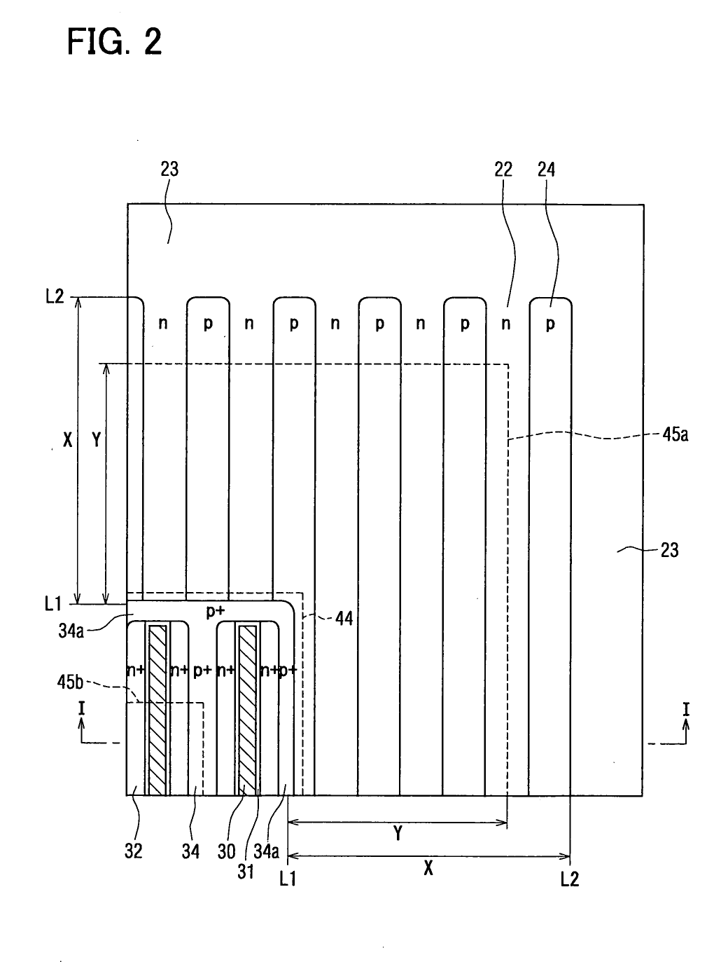

FIG. 2 is a top view of the device 1. In FIG. 2, the second semiconductor layer 28 is not shown so that the trench gate electrode 30 and the periodic construction 26 are explicitly described. Here, FIG. 1 is a cross sectional view showing the device 1 taken along line I-I in FIG. 2. In FIG. 2, a broken line 44 shows a periphery of the source electrode in the prior art. A broken line 45a shows an outer periphery of the source electrode 45 in the device 1 of this embodiment. Another broken line 45b shows an inner periphery of the source electrode 45 in the device 1. The source electrode 45 extends to the periphery portion 60 in the repeating direction of the periodic construction 26 and in a direction perpendicular to the repeating direction. Thus, the outer periphery 45a of the source electrode 45 is disposed in the periphery portion 60. Specifically, the outer periphery 45a is disposed inside of the outer periphery of the periodic construction 26. The inner periphery 45b of the source electrode 45 is disposed in the center portion 50. Thus, the source electrode is disposed between the inner periphery 45b and the outer periphery 45a. In this case, the extension of the source electrode 45 to the periphery portion 60 affects to increase the Off-state withstand voltage of the device 1. Thus, the device 1 has high withstand voltage.

Although the trench gate electrode 30 in the device 1 is perpendicular to the repeating direction of the periodic construction 26, the trench gate electrode 30 can be parallel to the repeating direction of the periodic construction 26. Further, the electrode 30 can tilt to have a predetermined angle between the electrode 30 and the repeating direction of the periodic construction 26. Furthermore, the trench gate electrode 30 can have a lattice shape or the like.

The first and second regions 22, 24 having the thin plate shape in the periodic construction 26 are alternately disposed in one direction as the repeating direction. However, the first and second regions 22, 24 can have a columnar shape. In this case, the first and second regions 22, 24 are alternately repeated in two directions. Specifically, the first and second regions 22, 24 are disposed in a grid. Further, the first and second regions 22, 24 can have a hexagonal cylinder shape. In this case, the first and second regions 22, 24 are alternately repeated in three directions. Further, another first and second regions having different conductive type can be dotted in the periphery portion 60.

### Second Embodiment

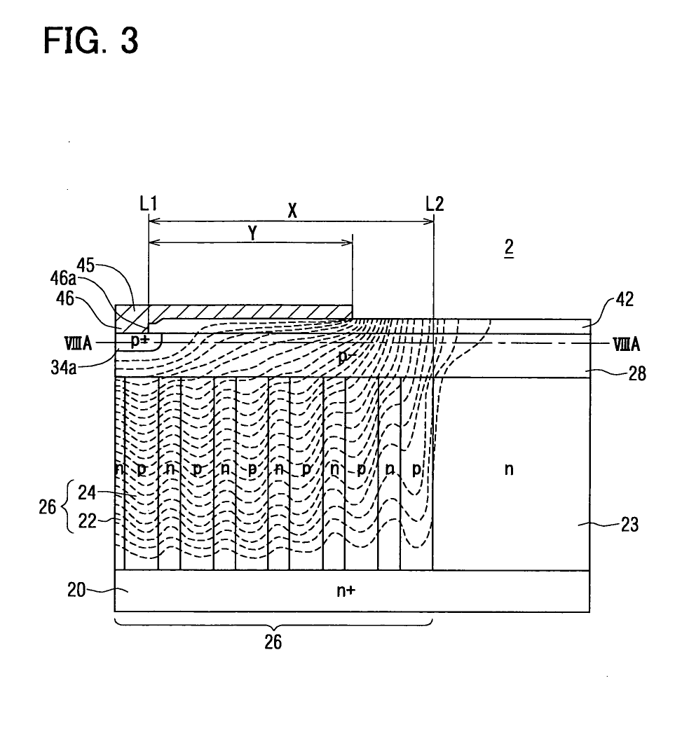

A semiconductor device 2 according to a second embodiment of the present invention is shown in FIG. 3. FIG. 3 is a partial cross sectional view showing the device 1 in FIG. 1. FIG. 3 shows an equipotential line distribution of a brake down voltage. Each broken line shows an equipotential line so that the brake down voltage on the same broken line is constant. The brake down voltage is determined in a case where a positive voltage is applied to the first semiconductor layer 20 and the potential of the source electrode 45 is set to be zero. In the device 2, a charge valance between the N type column 22 as the first region and the P type column 24 as the second region is held appropriately. The extension length Y of the source electrode 45 is three-fourths of the distance X between the line L1 and the end line L2. Five units composed of the N type column 22 and the P type column 24 are disposed between the line L1 and the end line L2.

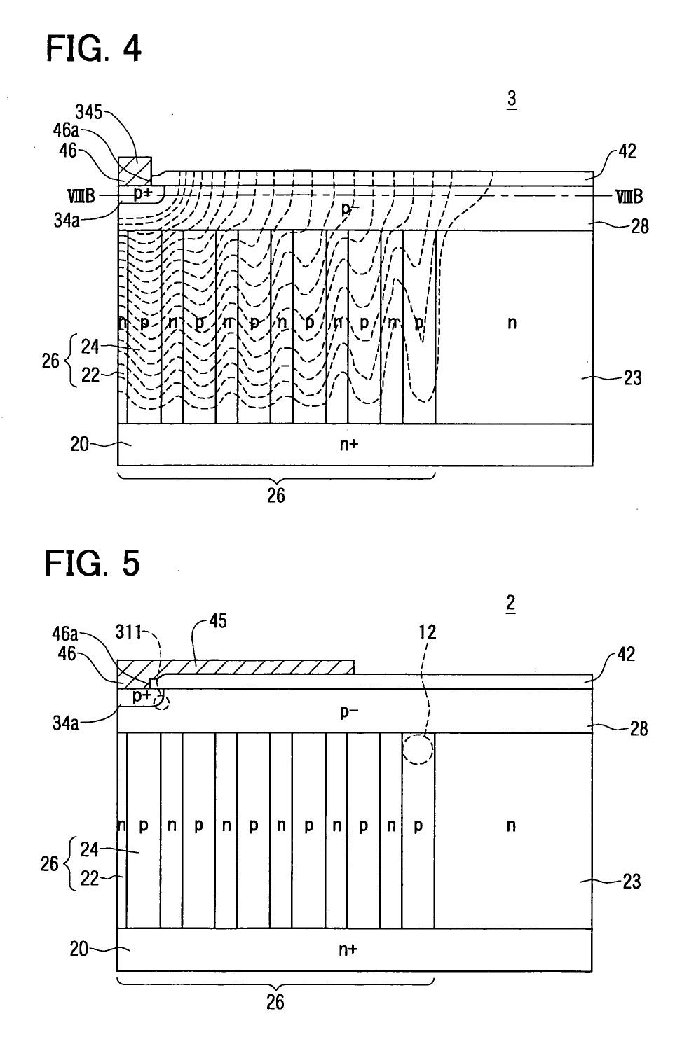

Another semiconductor device 3 as a comparison of the device 2 is shown in FIG. 4. The device 3 includes a short source electrode 345. The short source electrode 345 is disposed in the center portion only. Therefore, the short source electrode 345 does not extend to the periphery portion 60. Specifically, the outer periphery of the short source electrode 345 is disposed on the utmost outer contact region 34a. FIG. 4 also shows the equipotential line distribution of the brake down voltage of the device 3.

In the device 3 shown in FIG. 4, the equipotential line distribution near a corner of the utmost outer contact region 34a becomes dense (i.e., high density) so that the electric field is concentrated at the corner. Specifically, the equipotential lines are concentrated at the corner of the utmost contact region 34a, which has a large curvature. However, in the device 2 shown in FIG. 3, the equipotential line distribution near the corner of the contact region 34a become dilutes (i.e., low density) so that the electric field concentration is reduced at the corner. Thus, since the source electrode 45 in the device 2 extends to the periphery portion on the insulation layer 42, the electric field concentration is reduced at the corner.

FIG. 5 shows a portion 12 of the device 2, at which an impact ionization ratio becomes maximum. Here, a portion 311 is also shown as the comparison. In the device 3 shown in FIG. 4, the impact ionization ratio becomes maximum at the portion 311 near the corner of the utmost outer contact region 34a. However, in the device 2 according to the second embodiment, the impact ionization ratio becomes maximum at the portion 12 disposed in the utmost outer P type column 24. Since the electrode 45 is formed on the insulation layer 42, the impact ion is easily occurred the portion 12. Thus, the impact ion easily generation portion shifts from the portion 311 to the portion 12. Specifically, the impact ion easily generation portion shifts from the corner of the utmost outer contact region 34a to the upper portion of the column adjacent to the end region 23. In FIG. 5, the impact ion easily generation portion is disposed on the upper portion of the utmost outer P type column 24. In this case, the Off-state withstand voltage is increased, since the impact ion easily generation portion is disposed far from the source electrode 45. Here, the Off-state withstand voltage of the device 2 is 264V, and the Off-state withstand voltage of the device 3 is 218V. Therefore, the Off-state withstand voltage of the device 2 is higher than that of the device 3.

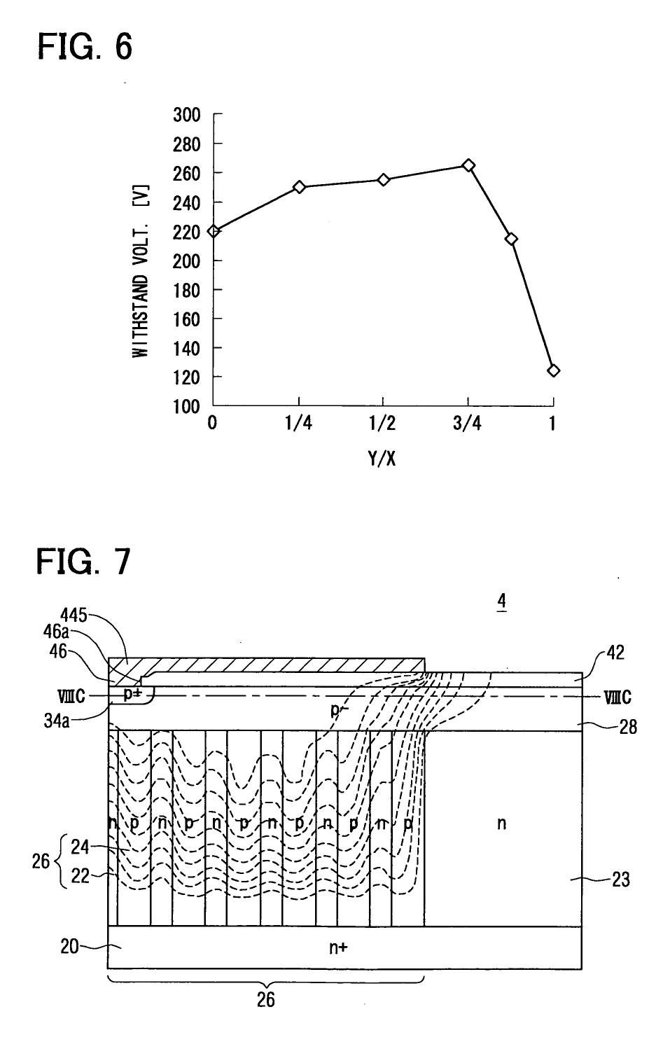

FIG. 6 shows a relationship between the extension length Y and the withstand voltage of the device 2. Specifically, the horizontal axis in FIG. 6 shows a ratio between the extension length Y and the distance X. Accordingly, when the ratio is zero, the electrode 45 does not extend to the periphery portion 50. This is, the case where the ratio is zero expresses the device 3 shown in FIG. 4. When the ratio is 1.0, the electrode 45 extends to the line L2 disposed at the interface between the periodic construction 26 and the end region 23. A shown in FIG. 6, when the ratio between the extension length Y and the distance X is in a range between 0 and ⅞, the withstand voltage of the device 2 is increased, compared with the device 3 shown in FIG. 4. However, when the electrode 45 extends to the line L2 disposed at the interface between the periodic construction 26 and the end region 23, the Off-state withstand voltage of the device 4 is decreased. Here, the ratio between the extension length Y and the distance X is 1.0. In this case, the device 4 having the longest electrode length of the source electrode 445 shows the equipotential line distribution shown in FIG. 7. When the electrode 445 extends to the end line L2, the depletion layer near the outer end of the electrode 445 becomes dense. Therefore, the electric field is concentrated at that portion so that the Off-state withstand voltage of the device 4 is decreased.

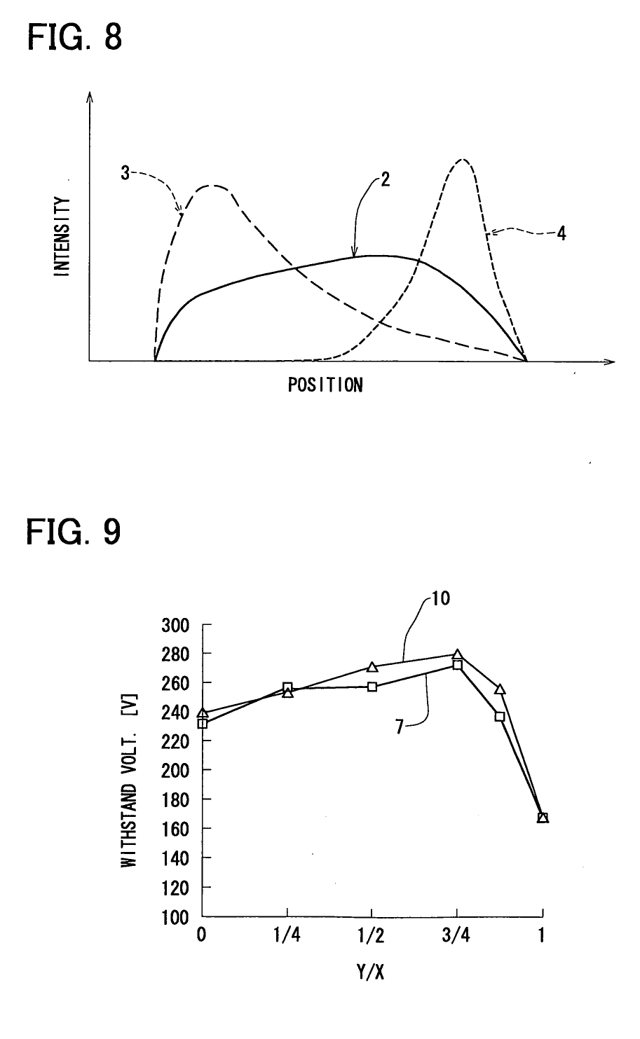

FIG. 8 shows the electric field intensity distribution of the devices 2-4. Specifically, a curve 2 in FIG. 8 represents the electric field intensity distribution of the device 2 shown in FIG. 3. The electric field intensity distribution of the curve 2 is measured along with the line VIIIA-VIIIA in FIG. 3. Curves 3, 4 represent the distributions of the devices 3, 4, and the distribution of each curve 3, 4 is measured along with line VIIIB-VIIIB in FIG. 4 or line VIIIC-VIIIC in FIG. 7. The horizontal axis represents a position on the line VIIIA-VIIIA, VIIIB-VIIIB, or VIIIC-VIIIC. The vertical axis represents the electric field intensity of each device 2-4. As shown in FIG. 8, in the device 3, i.e., in the curve 3, the electric field intensity has a peak at the interface between the contact region 34a and the second semiconductor layer 28. However, in the device 2, i.e., in the curve 2, the electric field is uniformed so that the electric field at the interface between the contact region 34a and the second semiconductor layer 28 is reduced. Thus, the electric field intensity is uniformed in the second semiconductor layer 28. However, in the device 4, i.e., in the curve 4, the equipotential line distribution is much changed so that the electric field intensity near the interface between the periodic construction 60 and the end region 23 is increased so that the intensity distribution has the peak at the interface. Thus, the Off-state withstand voltage is decreased.

Here, in the prior art, to increase a withstand voltage, a field plate method is used. In the field plate method, a depletion layer at an interface between a contact region and a semiconductor region having opposite conductive type opposite to the contact region is expanded so that electric field concentration at the interface is reduced. Here, the interface provides a P-N junction.

However, in FIG. 8, the depletion layer is not expanded substantially. The extension of the electrode 45 causes not to expand the depletion layer but to uniform the electric field intensity in the depletion layer. Thus the withstand voltage of the device is increased. Further, in the field plate method according to the prior art, the electric field concentration at the P-N junction is reduced. However, in the device 2 shown in FIG. 3, the electric field concentration at the interface between the P⁺ type contact region 34a and the P⁻ type second semiconductor layer 28, which are the same conductive type is reduced. Therefore, the field plate method is different from the present invention.

### Third Embodiment

A semiconductor devices 7, 10 according to a third embodiment of the present invention have different numbers of the units composed of the N type column 22 and the P type column 24. Specifically, the device 7 has seven units, and the device 10 has ten units, although the device 2 has five units. FIG. 9 shows a relationship between the withstand voltage and the ratio of the extension length Y and the distance X. Curve 7 represents the device 7, and curve 10 represents the device 10.

As shown in FIGS. 8 and 10, the withstand voltage of each device 2, 7, 10 is increased without depending on the number of the units of the periodic construction 26 substantially. Therefore, the ratio of the extension length Y and the distance X mainly affects the increase of the withstand voltage of the device 2, 7, 10. Further, when the electrode 45 extends to the interface between the periodic construction 26 and the end region 23, i.e., when the ratio of the extension length Y is one, the withstand voltage of the device 2, 7, 10 becomes lower. Therefore, when the ration of the extension length Y is in a range between 0 and seven-eighths of the distance X, the withstand voltage of the device 2, 7, 10 is increased.

Such changes and modifications are to be understood as being within the scope of the present invention as defined by the appended claims.

1. A device comprising:
a center portion; and
a periphery portion disposed around the center portion,
wherein the periphery portion includes a first semiconductor layer, an intermediate layer, a second semiconductor layer, an insulation layer and an electrode, which are laminated in this order,
wherein the intermediate layer includes a periodic construction having a first region and a second region, which are repeated alternately in a repeating direction parallel to the first and second semiconductor layers,
wherein the center portion includes a contact region,
wherein the electrode extends to the periphery portion to have an extension length of the electrode, which is defined as a length of the electrode between the contact region and an outer periphery of the electrode disposed in the periphery portion, and
wherein the extension length of the electrode is equal to or longer than one-eighth of a distance between the contact region and an outer periphery of the periodic construction.

2. The device according to claim 1,
wherein the center portion includes a semiconductor switching device,
wherein the periphery portion includes no semiconductor switching device,
wherein the first semiconductor layer has a first conductive type, and the second semiconductor layer has a second conductive type,
wherein the intermediate layer divides the first and second semiconductor layers,
wherein the first region of the periodic construction has the first conductive type, and the second region of the periodic construction has the second conductive type,
wherein the center portion includes multiple contact regions having the second conductive type so that an utmost outer contact region is disposed on utmost outside of the center portion,
wherein the electrode contacts the contact regions, and is electrically connected to the second semiconductor layer in the periphery portion through the utmost outer contact region, and
wherein the extension length of the electrode is defined a length between the utmost outer contact region and the outer periphery of the electrode disposed in the periphery portion.

3. The device according to claim 2,
wherein the first semiconductor layer is disposed on a backside of the device, and the second semiconductor layer is disposed on a foreside of the device,
wherein the insulation layer is disposed on a part of the second semiconductor layer,
wherein the electrode is disposed on a part of the insulation layer and on another part of the second semiconductor layer, and
wherein the first region extends between the first semiconductor layer and the second semiconductor layer, and the second region extends between the second semiconductor layer and the first semiconductor layer.

4. The device according to claim 1,
wherein the extension length of the electrode is in a range between one-eighth and seven-eighths of the distance between the contact region and the outer periphery of the periodic construction.

5. The device according to claim 1,
wherein the periodic construction extends to the center portion so that both of the center portion and the periphery portion include the periodic construction.

6. The device according to claim 2,
wherein the first conductive type is a N conductive type, and the second conductive type is a P conductive type,
wherein the first region provides a N type column, and the second region provides a P type column,
wherein the second semiconductor layer has a light doped P conductive type, and
wherein the contact region has a heavy doped P conductive type.

7. The device according to claim 2,
wherein the first conductive type is a N conductive type, and the second conductive type is a P conductive type, and
wherein the contact region includes a P conductive type impurity, a concentration of which is higher than that of a P conductive type impurity in the second semiconductor layer.

8. The device according to claim 1, further comprising:
a trench gate electrode disposed in the second semiconductor layer; and
a source region disposed on the second semiconductor layer,
wherein the electrode is a source electrode,
wherein the first semiconductor layer provides a drain region, the periodic construction provides a drift region, and the second semiconductor layer provides a body region so that the center portion provides a trench gate type metal oxide semiconductor transistor.

9. A device comprising:
a center portion having a semiconductor switching device; and
a periphery portion disposed around the center portion and having no semiconductor switching device,
wherein the periphery portion includes a first semiconductor layer having a first conductive type and disposed on a backside of the device, an intermediate layer, a second semiconductor layer having a second conductive type and disposed on a foreside of the device, an insulation layer, and an electrode, which are disposed in this order,
wherein the intermediate layer divides the first and second semiconductor layers,
wherein the insulation layer is disposed on a part of the second semiconductor layer,
wherein the electrode is disposed on a part of the insulation layer and on another part of the second semiconductor layer,
wherein the intermediate layer includes a periodic construction having a first region with the first conductive type and a second region with the second conductive type, which are repeated alternately in a repeating direction parallel to the first and second semiconductor layers,
wherein the first region extends from the first semiconductor layer to the second semiconductor layer, and the second region extends from the second semiconductor layer to the first semiconductor layer,
wherein the center portion includes multiple contact regions having the second conductive type so that an utmost outer contact region is disposed on utmost outside of the center portion,
wherein the electrode contacts the contact regions, and is electrically connected to the second semiconductor layer in the periphery portion through the utmost outer contact region, and
wherein the electrode exceeds the first or second region adjacent to the utmost outer contact region and extends to the periphery portion.

10. The device according to claim 9,
wherein the electrode extends within an outer periphery of the periodic construction.

11. The device according to claim 9,
wherein the periodic construction extends to the center portion so that both of the center portion and the periphery portion include the periodic construction.

12. The device according to claim 9,
wherein the electrode has an extension length in a range between one-eighth and seven-eighths of a distance between the contact region and an outer periphery of the periodic construction.

13. The device according to claim 9,
wherein the first conductive type is a N conductive type, and the second conductive type is a P conductive type,
wherein the first region provides a N type column, and the second region provides a P type column,
wherein the second semiconductor layer has a light doped P conductive type, and
wherein the contact region has a heavy doped P conductive type.

14. The device according to claim 9,
wherein the first conductive type is a N conductive type, and the second conductive type is a P conductive type, and
wherein the contact region includes a P conductive type impurity, a concentration of which is higher than that of a P conductive type impurity in the second semiconductor layer.

15. The device according to claim 9, further comprising:
a trench gate electrode disposed in the second semiconductor layer; and
a source region disposed on the second semiconductor layer,
wherein the electrode is a source electrode,
wherein the first semiconductor layer provides a drain region, the periodic construction provides a drift region, and the second semiconductor layer provides a body region so that the center portion provides a trench gate type metal oxide semiconductor transistor.

16. A device comprising:
a first semiconductor layer having a first conductive type and disposed on a backside of the device;
a second semiconductor layer having a second conductive type and disposed on a foreside of the device;
an intermediate layer for dividing the first and second semiconductor layers;
a contact region having the second conductive type and disposed on a part of the second semiconductor layer;
an insulation layer for covering a surface of the second semiconductor layer; and
an electrode disposed on the insulation layer,
wherein the intermediate layer includes a periodic construction having a first region with the first conductive type and a second region with the second conductive type, which are repeated alternately in a repeating direction parallel to the first and second semiconductor layers,
wherein the first region extends between the first semiconductor layer and the second semiconductor layer, and the second region extends between the second semiconductor layer and the first semiconductor layer,
wherein the electrode is electrically connected to the second semiconductor layer through the contact region, and
wherein the electrode exceeds the first or second region in the periodic construction adjacent to the contact region and extends on the insulation layer.

17. The device according to claim 16,
wherein the electrode extends within an outer periphery of the periodic construction.

18. The device according to claim 16,
wherein the electrode has an extension length in a range between one-eighth and seven-eighths of a distance between the contact region and an outer periphery of the periodic construction.

19. The device according to claim 16,
wherein the first conductive type is a N conductive type, and the second conductive type is a P conductive type,
wherein the first region provides a N type column, and the second region provides a P type column,
wherein the second semiconductor layer has a light doped P conductive type, and
wherein the contact region has a heavy doped P conductive type.

20. The device according to claim 16,
wherein the first conductive type is a N conductive type, and the second conductive type is a P conductive type, and
wherein the contact region includes a P conductive type impurity, a concentration of which is higher than that of a P conductive type impurity in the second semiconductor layer.

21. The device according to claim 16, further comprising:
a trench gate electrode disposed in the second semiconductor layer; and
a source region disposed on the second semiconductor layer,
wherein the electrode is a source electrode,
wherein the first semiconductor layer provides a drain region, the periodic construction provides a drift region, and the second semiconductor layer provides a body region so that the center portion provides a trench gate type metal oxide semiconductor transistor.
